(19) United States
(12) Patent Application Publication
(10) Pub. No.: US 2025/0349365 A1
(43) Pub. Date: Nov. 13, 2025

(54) MEMORY DEVICE AND ERASE OPERATION THEREOF

(71) Applicant: YANGTZE MEMORY TECHNOLOGIES CO., LTD., Wuhan (CN)

(72) Inventors: Xiaoya Yuan, Wuhan (CN); Xiangdong Lu, Wuhan (CN); Hongyu Ji, Wuhan (CN); Jie Cui, Wuhan (CN); Zhenjia Chen, Wuhan (CN); Wei Huang, Wuhan (CN); Chunyuan Hou, Wuhan (CN); Huazheng Wei, Wuhan (CN); Hong Cao, Wuhan (CN)

(21) Appl. No.: 18/671,452

(22) Filed: May 22, 2024

(30) Foreign Application Priority Data
May 8, 2024 (CN) 202410564764.7

(51) Int. Cl. G11C 16/16; G11C 16/04; G11C 16/34

(52) U.S. Cl. CPC G11C 16/16; G11C 16/0483; G11C 16/3445; G11C 16/349

(57) ABSTRACT

In certain aspects, a memory device includes at least a block of memory cells and a peripheral circuit coupled to the block of memory cells. The peripheral circuit is configured to apply a first set of erase pulses to erase the block of memory cells in a first set of erase cycles, respectively. The first set of erase pulses includes one or more first erase voltages having varied voltage values. Responsive to an erase cycle count reaching a cycle threshold, the peripheral circuit is further configured to apply a second set of erase pulses to erase the block of memory cells in a second set of erase cycles, respectively. The second set of erase pulses includes one or more second erase voltages each of which has a respective voltage value smaller than a voltage value of one of the one or more first erase voltages.

### CROSS-REFERENCE TO RELATED APPLICATIONS

This application claims the benefit of priority to Chinese Application No. 202410564764.7, filed on May 8, 2024, which is incorporated herein by reference in its entirety.

### BACKGROUND

The present disclosure relates to memory devices and operation methods thereof.

Non-volatile storage devices such as solid-state drives (SSDs), non-volatile memory express (NVMe), embedded multimedia cards (eMMCs), and universal flash storage (UFS) devices, etc., have gained significant popularity in recent years due to their numerous advantages over traditional hard disk drives (HDDs), such as faster read and write speed, durability and reliability, reduced power consumption, silent operation, and smaller form factors. For example, non-volatile storage devices such as SSDs may use NAND Flash memory for non-volatile storage. Various operations can be performed by NAND Flash memory, such as read, program (write), and erase. For NAND Flash memory, an erase operation can be performed at the block level, and a program operation or a read operation can be performed at the page level.

### SUMMARY

In one aspect, a method of operating a memory device that includes memory cells is disclosed. The method includes applying a first set of erase pulses to erase the block of memory cells in a first set of erase cycles, respectively. The first set of erase pulses includes one or more first erase voltages having varied voltage values. Responsive to an erase cycle count reaching a cycle threshold, the method further includes applying a second set of erase pulses to erase the block of memory cells in a second set of erase cycles, respectively. The second set of erase pulses includes one or more second erase voltages each of which has a respective voltage value smaller than a voltage value of one of the one or more first erase voltages.

In some implementations, the cycle threshold is in a range between 3 and 6.

In some implementations, the respective voltage value of each of the one or more second erase voltages is identical.

In some implementations, applying the first set of erase pulses to erase the block of memory cells in the first set of erase cycles, respectively, includes, in each of the first set of erase cycles and responsive to the erase cycle count being smaller than the cycle threshold, applying a corresponding first erase voltage to erase the block of memory cells, and applying a verify voltage to verify the erasing of the block of memory cells.

In some implementations, applying the second set of erase pulses to erase the block of memory cells in the second set of erase cycles, respectively, further includes, in each of the second set of erase cycles and responsive to the erase cycle count being equal to or greater than the cycle threshold and smaller than a maximum cycle count, applying a corresponding second erase voltage to erase the block of memory cells, and applying a verify voltage to verify the erasing of the block of memory cells.

In some implementations, the method further includes updating the erase cycle count that indicates a total number of erase cycles already performed to erase the block of memory cells.

In some implementations, the method further includes responsive to the erase cycle count reaching the maximum cycle count, terminating the erasing of the block of memory cells.

In some implementations, an increment step pulse erase (ISPE) scheme is applied to erase the block of memory cells. The one or more first erase voltages include one or more increment step pulses. The one or more second erase voltages include one or more pulses having an identical voltage value.

In another aspect, a memory device includes at least a block of memory cells and a peripheral circuit coupled to the block of memory cells. The peripheral circuit is configured to apply a first set of erase pulses to erase the block of memory cells in a first set of erase cycles, respectively. The first set of erase pulses includes one or more first erase voltages having varied voltage values. Responsive to an erase cycle count reaching a cycle threshold, the peripheral circuit is further configured to apply a second set of erase pulses to erase the block of memory cells in a second set of erase cycles, respectively. The second set of erase pulses includes one or more second erase voltages each of which has a respective voltage value smaller than a voltage value of one of the one or more first erase voltages.

In some implementations, the cycle threshold is in a range between 3 and 6.

In some implementations, the respective voltage value of each of the one or more second erase voltages is identical.

In some implementations, to apply the first set of erase pulses to erase the block of memory cells in the first set of erase cycles, respectively, the peripheral circuit is further configured to, in each of the first set of erase cycles and responsive to the erase cycle count being smaller than the cycle threshold, apply a corresponding first erase voltage to erase the block of memory cells, and apply a verify voltage to verify the erasing of the block of memory cells.

In some implementations, to apply the second set of erase pulses to erase the block of memory cells in the second set of erase cycles, respectively, the peripheral circuit is further configured to, in each of the second set of erase cycles and responsive to the erase cycle count being equal to or greater than the cycle threshold and smaller than a maximum cycle count, apply a corresponding second erase voltage to erase the block of memory cells, and apply a verify voltage to verify the erasing of the block of memory cells.

In some implementations, the peripheral circuit is further configured to update the erase cycle count that indicates a total number of erase cycles already performed to erase the block of memory cells.

In some implementations, the peripheral circuit is further configured to, responsive to the erase cycle count reaching the maximum cycle count, terminate the erasing of the block of memory cells.

In some implementations, an ISPE scheme is applied to erase the block of memory cells. The one or more first erase voltages include one or more increment step pulses. The one or more second erase voltages include one or more pulses having an identical voltage value.

In still another aspect, a system includes a memory device and a memory controller. The memory device is configured to store data, and includes at least a block of memory cells and a peripheral circuit coupled to the block of memory cells and configured to perform operations described herein. The memory controller is coupled to the memory device and configured to control the memory device to perform the operations. The operations include applying a first set of erase pulses to erase the block of memory cells in a first set of erase cycles, respectively. The first set of erase pulses includes one or more first erase voltages having varied voltage values. Responsive to an erase cycle count reaching a cycle threshold, the operations further include applying a second set of erase pulses to erase the block of memory cells in a second set of erase cycles, respectively. The second set of erase pulses includes one or more second erase voltages each of which has a respective voltage value smaller than a voltage value of one of the one or more first erase voltages.

In some implementations, the peripheral circuit includes at least one processor, a read-only memory (ROM) storing first instructions, and a random-access memory (RAM) storing second instructions. The first instructions include a first instruction segment, a second instruction segment, and a third instruction segment. The second instructions stored in the RAM are configured to replace the second instruction segment stored in the ROM. The at least one processor is configured to perform the operations by executing the first instruction segment stored in the ROM, the second instructions stored in the RAM, and the third instruction segment stored in the ROM.

In some implementations, the cycle threshold is in a range between 3 and 6.

In some implementations, the respective voltage value of each of the one or more second erase voltages is identical.

In some implementations, to apply the first set of erase pulses to erase the block of memory cells in the first set of erase cycles, respectively, the peripheral circuit is further configured to, in each of the first set of erase cycles and responsive to the erase cycle count being smaller than the cycle threshold, apply a corresponding first erase voltage to erase the block of memory cells, and apply a verify voltage to verify the erasing of the block of memory cells.

In some implementations, to apply the second set of erase pulses to erase the block of memory cells in the second set of erase cycles, respectively, the peripheral circuit is further configured to, in each of the second set of erase cycles and responsive to the erase cycle count being equal to or greater than the cycle threshold and smaller than a maximum cycle count, apply a corresponding second erase voltage to erase the block of memory cells, and apply a verify voltage to verify the erasing of the block of memory cells.

In some implementations, the peripheral circuit is further configured to update the erase cycle count that indicates a total number of erase cycles already performed to erase the block of memory cells.

In some implementations, the peripheral circuit is further configured to, responsive to the erase cycle count reaching the maximum cycle count, terminate the erasing of the block of memory cells.

In some implementations, an ISPE scheme is applied to erase the block of memory cells. The one or more first erase voltages include one or more increment step pulses. The one or more second erase voltages include one or more pulses having an identical voltage value.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a block diagram of a system having a memory device, according to some aspects of the present disclosure.

FIG. 2A illustrates a diagram of a memory card having a memory device, according to some aspects of the present disclosure.

FIG. 2B illustrates a diagram of a solid-state drive (SSD) having a memory device, according to some aspects of the present disclosure.

FIG. 3 illustrates a block diagram of a memory controller, according to some aspects of the present disclosure.

FIG. 4 illustrates a schematic diagram of a memory device including peripheral circuits, according to some aspects of the present disclosure.

FIG. 5A illustrates a block diagram of a memory device including a memory cell array and peripheral circuits, according to some aspects of the present disclosure.

FIG. 5B illustrates a block diagram of a control logic, according to some aspects of the present disclosure.

FIG. 5C illustrates an example implementation of modifying firmware codes stored in a read-only memory (ROM), according to some aspects of the present disclosure.

FIG. 6 illustrates a flowchart of a method for operating a memory device, according to some aspects of the present disclosure.

FIG. 7 illustrates a flowchart of another method for operating a memory device, according to some aspects of the present disclosure.

FIG. 8 illustrates a waveform of erase voltages and verify voltages applied in a plurality of erase cycles, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

A non-volatile (NV) memory device such as a NAND Flash memory device may perform an erase operation on memory cells that have been written, so that the memory cells can be erased. Subsequently, the erased memory cells can be programmed with new data. For a block of memory cells, the number of programs/erasures (also called program/erase (P/E) cycles) performed on the memory cells throughout the life span of the memory device can be limited. When the memory cells in the block are programmed frequently, the erasures on the block are also performed frequently. Once a maximum number of the P/E cycles is reached, this block can no longer be written. For example, for a block of single-level cells (SLCs), the maximum number of the P/E cycles is usually 100,000 times. For a block of multi-level cells (MLCs), the maximum number of the P/E cycles is usually more than 10,000 times. For a block of Triple-level cells (TLCs), the maximum number of the P/E cycles is reduced to thousands.

The present disclosure introduces an erase scheme that can limit the number of erasures (or P/E cycles) performed in the NAND Flash memory device throughout the life span of the memory device. The erase scheme can be applied with respect to an erase operation. The number of erasures performed in the erase operation can be referred to as “erase cycles.”

For example, in the erase operation, initially, a first set of erase cycles can be performed to erase a block of memory cells, and a first set of erase voltages can be applied in the first set of erase cycles, respectively. The first set of erase voltages can have varied voltage values. For example, the first set of erase voltages can be a set of increment step pulses. When the number of the erase cycles performed to erase the block of memory cells reaches a cycle threshold, a second set of erase cycles can be performed to erase the block of memory cells, where a second set of erase voltages can be applied in the second set of erase cycles, respectively. Different from the first set of erase voltages, the second set of erase voltages may have an identical voltage value. Because the voltage value of the erase voltages in the second set is not increased (e.g., keeps unchanged) when the number of the erase cycles is equal to or greater than the cycle threshold, the continuing erasures on the block by the second set of erase voltages may not succeed. Then, when the number of the erase cycles reaches a maximum erase cycle count for the erase operation, it is determined that the erase operation fails, and the block of memory cells may be marked as a bad block (e.g., a malfunctioned block).

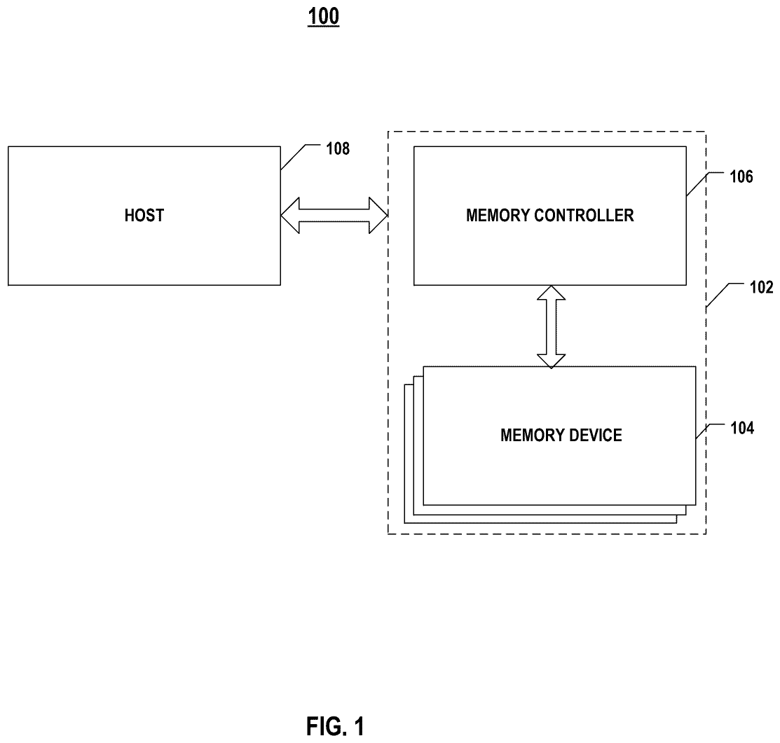

FIG. 1 illustrates a block diagram of a system 100 including a memory system 102, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive data (a.k.a. user data or host data) to or from memory system 102. Memory system 102 can be a storage product integrating memory controller 106 and one or more memory devices 104, such as an SSD.

Memory devices 104 can be any memory devices disclosed in the present disclosure, including non-volatile memory devices, such as NAND Flash memory devices. In some implementations, memory device 104 also includes one or more volatile memory devices, such as DRAM devices or static random-access memory (SRAM) devices.

Memory controller 106 is operatively coupled to memory devices 104 and host 108 and is configured to control memory devices 104, according to some implementations. Memory controller 106 can manage the data stored in memory devices 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment with SSDs or embedded multimedia card (eMMCs) used as data storage for mobile devices, such as smartphones, tablets, laptop computers, etc., and enterprise storage arrays. Memory controller 106 can be configured to control operations of memory devices 104, such as read, program/write, and/or erase operations. Memory controller 106 can also be configured to manage various functions with respect to the data stored or to be stored in memory devices 104 including, but not limited to bad-block management, garbage collection, logical-to-physical (L2P) address conversion, wear-leveling, etc. In some implementations, memory controller 106 is further configured to process error correction codes (ECCs) with respect to the data read from or written to memory devices 104. Any other suitable functions may be performed by memory controller 106 as well, for example, formatting memory devices 104. Memory controller 106 can communicate with an external device (e.g., host 108) according to a particular communication protocol. For example, memory controller 106 may communicate with the external device through at least one of various interface protocols, such as a non-volatile memory express (NVMe) protocol, an NVMe-over-fabrics (NVMe-oF) protocol, a PCI-express (PCI-E) protocol, a universal serial bus (USB) protocol, a multimedia card (MMC) protocol, a peripheral component interconnection (PCI) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

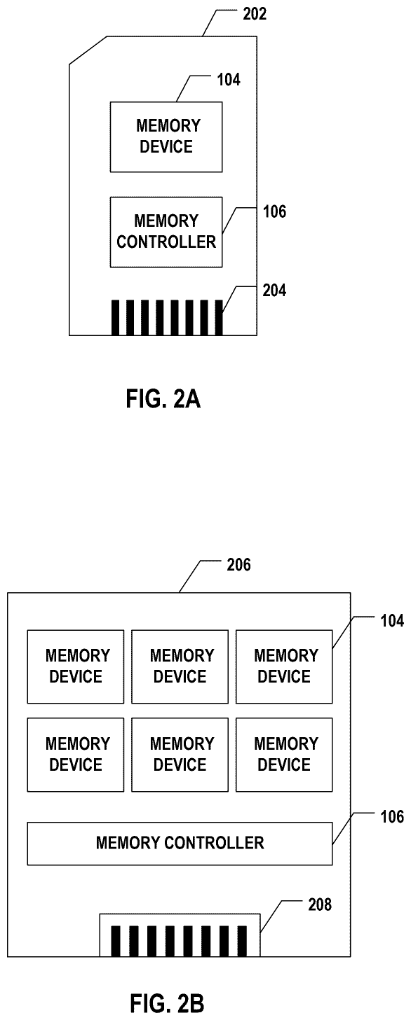

Memory controller 106 and one or more memory devices 104 can be integrated into various types of storage devices, for example, being included in the same package, such as a universal Flash storage (UFS) package or an eMMC package. That is, memory system 102 can be implemented and packaged into different types of end electronic products. In one example as shown in FIG. 2A, memory controller 106 and a single memory device 104 may be integrated into a memory card 202. Memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 can further include a memory card connector 204 coupling memory card 202 with a host (e.g., host 108 in FIG. 1). In another example as shown in FIG. 2B, memory controller 106 and multiple memory devices 104 may be integrated into an SSD 206. SSD 206 can further include an SSD connector 208 coupling SSD 206 with a host (e.g., host 108 in FIG. 1). In some implementations, the storage capacity and/or the operation speed of SSD 206 is greater than those of memory card 202. In some implementations, memory system 102 is implemented as an SSD 206 that includes both non-volatile memory devices and volatile memory devices as memory devices 104, such as an enterprise SSD.

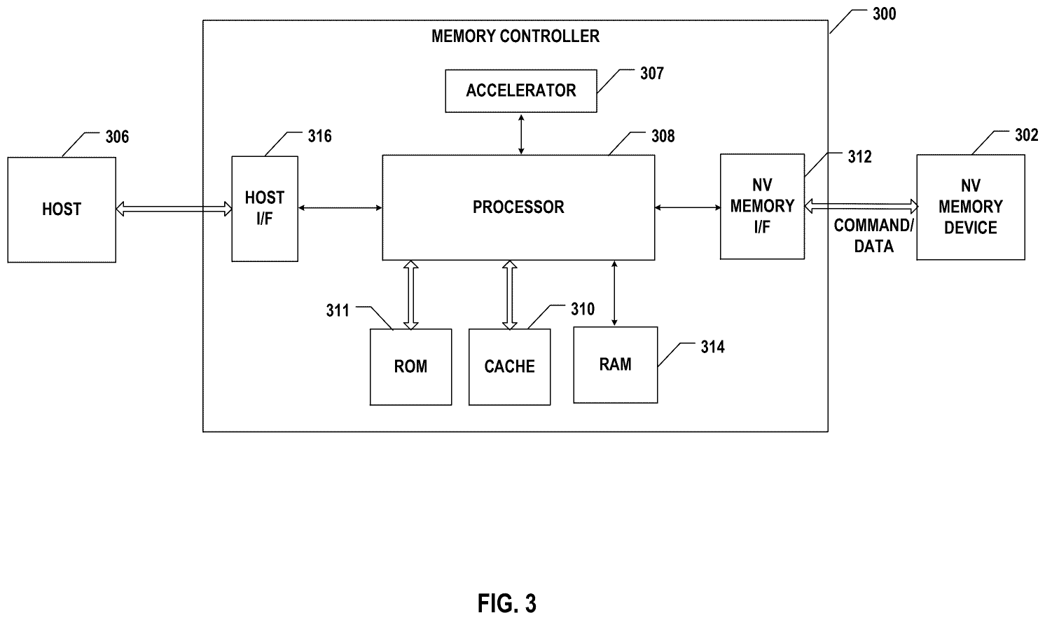

FIG. 3 illustrates a block diagram of a memory controller 300, according to some aspects of the present disclosure. Memory controller 300 may be one example of memory controller 106 in FIG. 1. As shown in FIG. 3, memory controller 300 can include a processor 308, an accelerator 307 (e.g., a hardware accelerator), a cache 310, and a read-only memory (ROM) 311. In some implementations, processor 308 is implemented by microprocessors (e.g., digital signal processors (DSPs)) or microcontrollers (a.k.a. microcontroller units (MCUs)) that execute firmware and/or software modules to perform the various functions described herein. The various firmware modules in memory controller 300 described herein can be implemented as firmware codes or instructions stored in ROM 311 and executed by processor 308. In some implementations, processor 308 includes one or more hardware circuits, for example, fixed logic units such as a logic gate, a multiplexer, a flip-flop, a state machine, field-programmable gate arrays (FPGAs), programmable logic devices (PLDs). For example, the hardware circuits may include dedicated circuits performing a given logic function that is known at the time of device manufacture, such as application-specific integrated circuits (ASICs).

Memory controller 300 can also include various input/output (I/O) interfaces (I/F), such as a non-volatile memory interface 312, a DRAM interface (not shown), and a host interface 316 operatively coupled to a non-volatile memory device 302 (e.g., flash memory), DRAM 304 (e.g., an example of volatile memory devices), and a host 306 (e.g., an example of host 108), respectively. Non-volatile memory interface 312, DRAM interface, and host interface 316 can be configured to transfer data, command, clock, or any suitable signals between processor 308 and non-volatile memory device 302, DRAM 304, and host 306, respectively. Non-volatile memory interface 312, DRAM interface 314, and host interface 316 can implement any suitable communication protocols facilitating data transfer, communication, and management, such as the NVMe protocol and PCI-E protocol, double data rate (DDR) protocol, to name a few.

As described above, both cache 310 and DRAM 304 may be considered volatile memory devices that can be controlled and accessed by memory controller 300 in a memory system. In some implementations, a cache can be implemented as part of volatile memory devices, for example, by an SRAM and/or DRAM 304. It is understood that although FIG. 3 shows that cache 310 is within memory controller 300 and DRAM 304 is outside of memory controller 300. In some examples, both cache 310 and DRAM 304 may be within memory controller 300 or outside of memory controller 300.

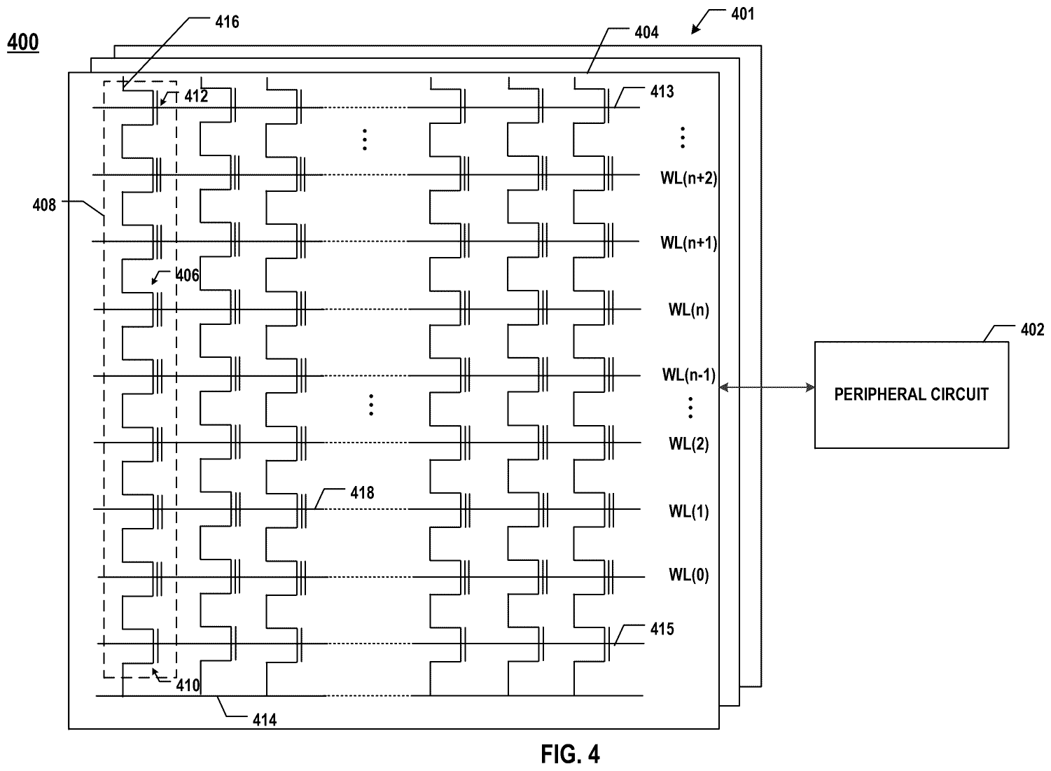

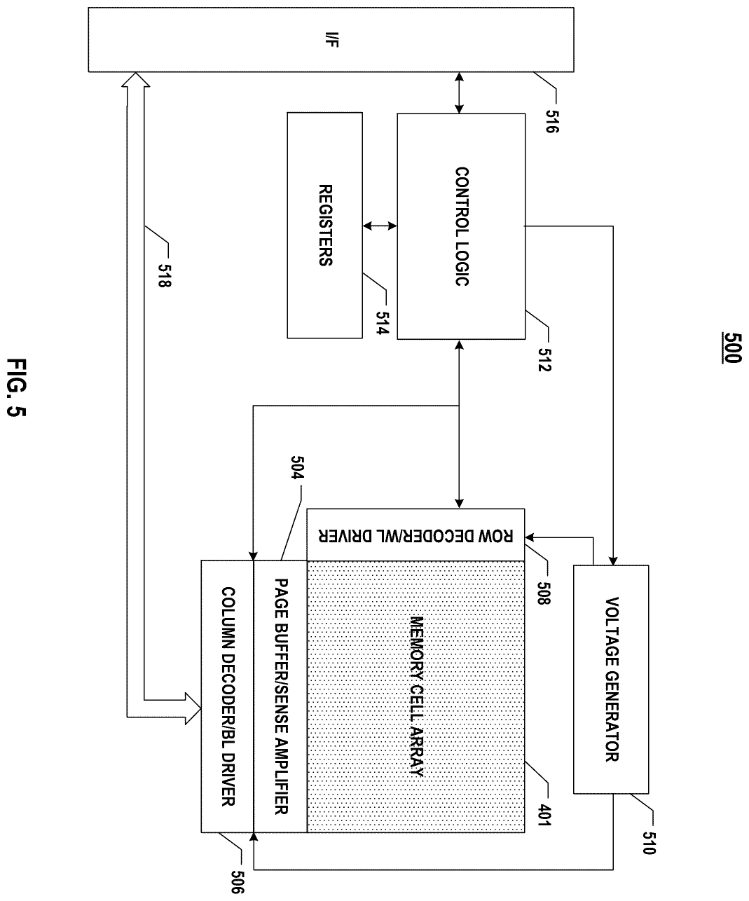

FIG. 4 illustrates a schematic diagram of a memory device 400 including peripheral circuits 402, according to some aspects of the present disclosure. Memory device 400 can be an example of memory device 104 in FIG. 1. Memory device 400 can include a memory cell array 401 and peripheral circuits 402 coupled to memory cell array 401. Memory cell array 401 can be a NAND Flash memory cell array in which memory cells 406 are provided in an array of NAND memory strings 408 each extending vertically above a substrate (not shown). In some implementations, each NAND memory string 408 includes a plurality of memory cells 406 coupled in series and stacked vertically. Each memory cell 406 can hold a continuous, analog value, such as an electrical voltage or charge, that depends on the number of electrons trapped within a region of memory cell 406. Each memory cell 406 can be either a floating gate type of memory cell including a floating-gate transistor or a charge trap type of memory cell including a charge-trap transistor.

In some implementations, each memory cell 406 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 406 is a multi-level cell (MLC) that is capable of storing more than a single bit of data in more than four memory states. For example, the MLC can store two bits per cell, three bits per cell (also known as TLC), or four bits per cell (also known as QLC). Each MLC can be programmed to assume a range of possible nominal storage values. In one example, if each MLC stores two bits of data, then the MLC can be programmed to assume one of three possible program levels from an erased state by writing one of three possible nominal storage values to the cell. A fourth nominal storage value can be used for the erased state.

As shown in FIG. 4, each NAND memory string 408 can also include a source select gate (SSG) transistor 410 at its source end and a drain select gate (DSG) transistor 412 at its drain end. SSG transistor 410 and DSG transistor 412 can be configured to activate select NAND memory strings 408 (columns of the array) during read and program operations. In some implementations, the sources of NAND memory strings 408 in the same block 404 are coupled through a same source line (SL) 414, e.g., a common SL. In other words, all NAND memory strings 408 in the same block 404 have an array common source (ACS), according to some implementations. The drain of each NAND memory string 408 is coupled to a respective bit line 416 from which data can be read or written via an output bus (not shown), according to some implementations. In some implementations, each NAND memory string 408 is configured to be selected or deselected by applying a DSG select voltage or a DSG unselect voltage to the gate of respective DSG transistor 412 through one or more DSG lines 413 and/or by applying an SSG select voltage or an SSG unselect voltage to the gate of respective SSG transistor 410 through one or more SSG lines 415.

As shown in FIG. 4, NAND memory strings 408 can be organized into multiple blocks 404, each of which can have a common source line 414, e.g., coupled to an ACS. In some implementations, each block 404 is the basic data unit for erase operations, i.e., all memory cells 406 on the same block 404 are erased at the same time. To erase memory cells 406 in a select block 404, source lines 414 coupled to select block 404 as well as unselect blocks 404 in the same plane as select block 404 can be biased with an erase voltage (Vers), such as a high positive voltage (e.g., 20 V or more). Memory cells 406 of adjacent NAND memory strings 408 can be coupled through word lines 418 that select which row of memory cells 406 is affected by read and program operations. Each word line 418 can include a plurality of control gates (gate electrodes) at each memory cell 406 coupled to word line 418 and a gate line coupling the control gates. With reference to FIG. 4, a plurality of word lines WL(0), WL(1), WL(2), . . . , WL(n−1), WL(n), WL(n+1), and WL(n+2) are illustrated, with n being a positive integer.

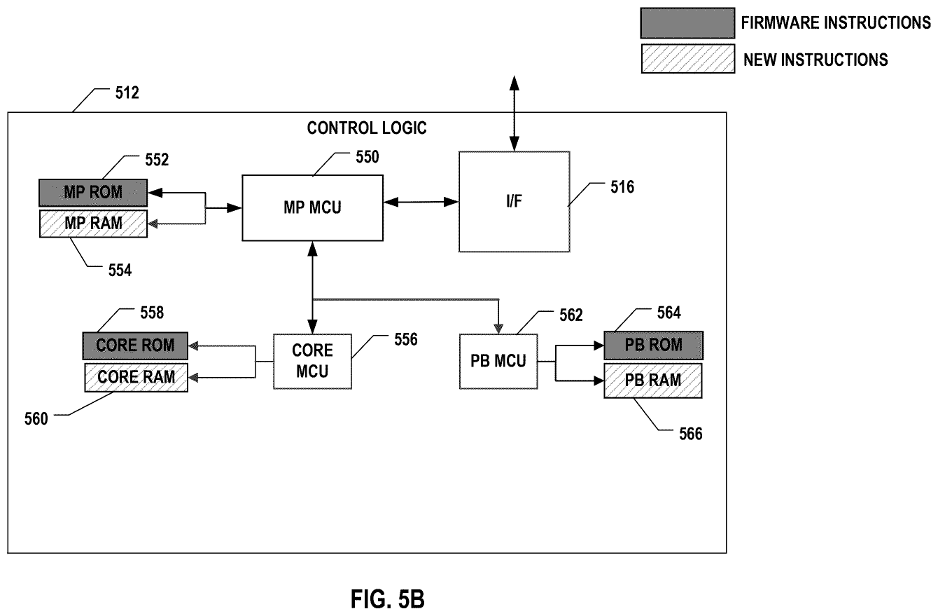

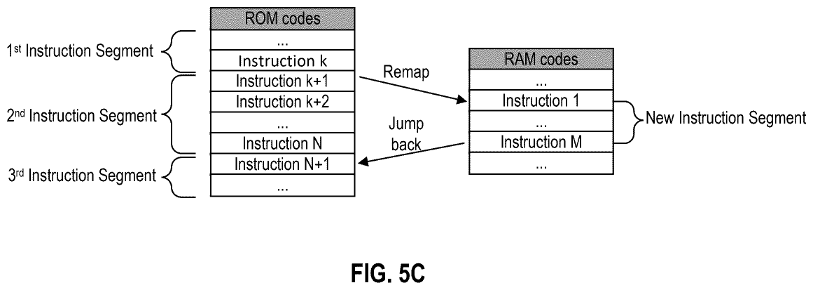

Peripheral circuits 402 can be coupled to memory cell array 401 through bit lines 416, word lines 418, source lines 414, SSG lines 415, and DSG lines 413. Peripheral circuits 402 can include any suitable analog, digital, and mixed-signal circuits for facilitating the operations of memory cell array 401 by applying and sensing voltage signals and/or current signals to and from each target memory cell 406 through bit lines 416, word lines 418, source lines 414, SSG lines 415, and DSG lines 413. Peripheral circuits 402 can include various types of peripheral circuits formed using metal-oxide-semiconductor (MOS) technologies. For example, FIG. 5A illustrates some peripheral circuits including a page buffer/sense amplifier 504, a column decoder/bit line driver 506, a row decoder/word line driver 508, a voltage generator 510, control logic 512, registers 514, an interface 516, and a data bus 518. It is understood that in some examples, additional peripheral circuits not shown in FIG. 5A may be included as well.

Page buffer/sense amplifier 504 can be configured to read and program (write) data from and to memory cell array 401 according to the control signals from control logic 512. In one example, page buffer/sense amplifier 504 may store one page of program data (write data) to be programmed into a page of memory cell array 401. In another example, page buffer/sense amplifier 504 may verify programmed target memory cells 406 in each program/verify loop (cycle) in a program operation to ensure that the data has been properly programmed into memory cells 406 coupled to select word lines 418. In still another example, page buffer/sense amplifier 504 may also sense the low power signals from bit line 416 that represents a data bit stored in memory cell 406 and amplify the small voltage swing to recognizable logic levels in a read operation. In program operations, page buffer/sense amplifier 504 can include storage modules (e.g., latches, caches, registers, etc.) for temporarily storing a set of N-bits data (e.g., in the form of gray codes) received from data bus 518 and providing the set of N-bits data to a corresponding target memory cell 406 through the corresponding bit line 416 in each program pass of a multi-pass program operation.

Column decoder/bit line driver 506 can be configured to be controlled by control logic 512 and select one or more NAND memory strings 408 by applying bit line voltages generated from voltage generator 510. Row decoder/word line driver 508 can be configured to be controlled by control logic 512 and select/deselect blocks 404 of memory cell array 401 and select/deselect word lines 418 of block 404. Row decoder/word line driver 508 can be further configured to drive word lines 418 using word line voltages generated from voltage generator 510. In some implementations, row decoder/word line driver 508 can also select/deselect and drive SSG lines 415 and DSG lines 413 as well. Voltage generator 510 can be configured to be controlled by control logic 512 and generate the word line voltages (e.g., read voltage, program voltage, channel pass voltage, local voltage, verify voltage, etc.), bit line voltages, and source line voltages to be supplied to memory cell array 401.

Control logic 512 can be coupled to each peripheral circuit described above and configured to control the operations of each peripheral circuit. Registers 514 can be coupled to control logic 512 and include status registers, command registers, and address registers for storing status information, command operation codes (OP codes), and command addresses for controlling the operations of each peripheral circuit. Interface 516 can be coupled to control logic 512 and act as a control buffer to buffer and relay control commands received from a host (e.g., 108 in FIG. 1) to control logic 512 and status information received from control logic 512 to the host. Interface 516 can also be coupled to column decoder/bit line driver 506 via data bus 518 and act as a data input/output (I/O) interface and a data buffer to buffer and relay the data to and from memory cell array 401.

FIG. 5B illustrates a block diagram of a control logic (e.g., control logic 512 of FIG. 5A), according to some aspects of the present disclosure. Control logic 512 may include a plurality of processors, a plurality of ROMs respectively coupled to the plurality of processors, a plurality of RAMs respectively coupled to the plurality of processors, and a plurality of registers (REG) coupled to the plurality of processors. For example, the plurality of processors may include a main processing (MP) microcontroller unit (MCU) 550, a core MCU 556, and a page buffer (PB) MCU 562. An MP ROM 552 and an MP RAM 554 can be coupled to MP MCU 550. A core ROM 558 and a core RAM 560 can be coupled to core MCU 556. A PB ROM 564 and a PB RAM 566 can be coupled to PB MCU 562. In some implementations, control logic 512 may further include interface 516 of FIG. 5A. That is, interface 516 can be part of control logic 512.

With respect to each MCU depicted in FIG. 5B, firmware codes (or firmware instructions) can be stored in a respective ROM coupled to the MCU and can be executed by the MCU. In some implementations, a segment of the firmware instructions stored in the respective ROM may need to be modified. In this case, new instructions can be stored in a respective RAM coupled to the MCU, and can be executed by the MCU in place of the segment of the firmware instructions.

For example, FIG. 5C illustrates an example implementation of modifying firmware codes stored in a ROM, according to some aspects of the present disclosure. In FIG. 5C, the firmware codes may include at least a first instruction segment, a second instruction segment, and a third instruction segment. The ROM and a RAM may be coupled to the same MCU. When the second instruction segment needs to be modified, a new instruction segment can replace the second instruction segment and be stored in the RAM. Then, the MCU may execute the firmware codes by first executing the first instruction segment from the ROM, then executing the new instruction segment from the RAM, and returning to execute the third instruction segment from the ROM. By storing the new instruction segment in the RAM, the firmware codes that are already stored in the ROM can be modified easily (e.g., with no need to change the hardware of the memory device). As a result, the cost of the memory device can be reduced while the performance of the memory device can be improved.

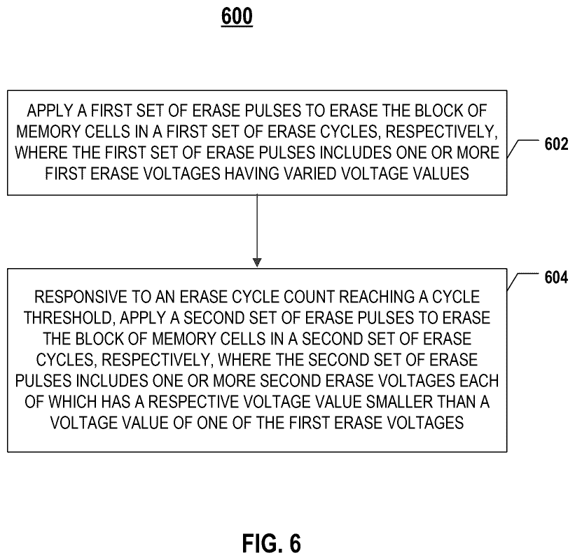

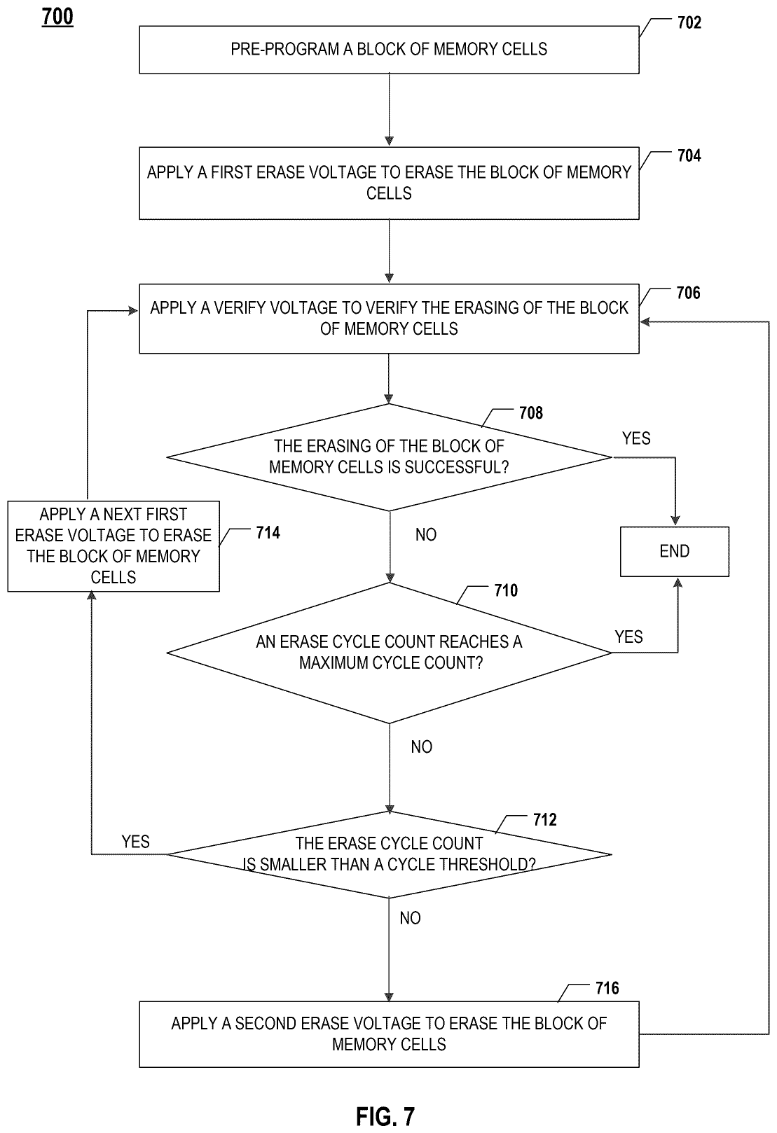

Consistent with some aspects of the present disclosure, an erase scheme disclosed herein can be applied in a memory device to limit the number of erasures applied to the memory device. Example implementations of the erase scheme are provided below with reference to FIGS. 6-8. FIGS. 6-8 are described below with reference to peripheral circuits 402 of FIG. 4. In some implementations, peripheral circuits 402 (e.g., control logic 512 of peripheral circuits 402) may include at least a processor, a ROM storing first instructions, and a RAM storing second instructions. The first instructions may include a first instruction segment, a second instruction segment, and a third instruction segment. The second instructions stored in the RAM may be new instructions and configured to replace the second instruction segment stored in the ROM. For example, the second instruction segment in the ROM can be modified to be the second instructions stored in the RAM. The processor may be configured to perform operations disclosed in FIGS. 6-7 by executing the first instruction segment stored in the ROM, the second instructions stored in the RAM, and the third instruction segment stored in the ROM.

For example, referring back to FIG. 5B, the processor may be MP MCU 550, and the ROM and RAM can be MP ROM 552 and MP RAM 554 of FIG. 5B, respectively. In another example, the processor may be core MCU 556, and the ROM and the RAM may be core ROM 558 and core RAM 560, respectively. In still another example, the processor may be PB MCU 562, and the ROM and the RAM may be PB ROM 564 and PB RAM 566, respectively.

Consistent with some aspects of the present disclosure, an erase operation may be performed on a block of memory cells (e.g., block 404 of FIG. 4). The erase operation may include one or more erase cycles (e.g., one or more erasures on the block and one or more corresponding verifications for the one or more erasures). To erase the memory cells in the block during an erase cycle, peripheral circuits 402 (such as row decoder/word line driver 508) can be configured to select the block from memory cell array 401. Then, source line (e.g., source line 414 or an ACS) coupled to the block can be biased with an erase voltage (Vers), such as a high positive voltage (e.g., 20 V or more), to erase the block. Following the application of the erase voltage (Vers) to the source line, a verify voltage can be applied to word lines coupled to the block to determine whether threshold voltages of the memory cells in the block become smaller than the verify voltage. If the threshold voltages of the memory cells are smaller than the verify voltage, indicating that the memory cells are in the erased state P0, the erasing of the block by the erase voltage is successful. For example, if threshold voltages of a predetermined percentage, such as 95% or 99% of the memory cells in the block are smaller than the verify voltage, the erasing of the block by the erase voltage is successful. Otherwise, the erasing of the block by the erase voltage fails, and the block can then be erased by applying the next erase cycle. Erase voltages in different erase cycles may have different voltage values (e.g., gradually increased voltage values). When an erase cycle count reaches a cycle threshold, erase voltages applied in subsequent erase cycles may have an identical voltage value. The erasures on the block may end when (a) the erase cycle count reaches a maximum cycle count for the erase operation or (b) the erasing of the memory cells is successful before the erase cycle count reaches the maximum cycle count. When the erase cycle count reaches the maximum cycle count, and the erasing of the block is not successful yet, the erase operation on the block fails.

Consistent with some aspects of the present disclosure, the erase cycle count may be indicative of the number of erase cycles already performed to erase the block of memory cells in the erase operation. The erase cycle count can be updated as more erase cycles are performed in the erase operation. The maximum cycle count may indicate the maximal number of erase cycles that can be used to erase the block during the erase operation.

FIG. 6 illustrates a flowchart of a method 600 for operating a memory device, according to some aspects of the present disclosure. The memory device may be any suitable memory device disclosed herein, such as memory device 104, 302, or 400. The memory device may include at least a block of memory cells. Method 600 may be implemented by peripheral circuits 402, such as control logic 512, row decoder/word line driver 508, and page buffer/sense amplifier 504. It is understood that the operations shown in method 600 may not be exhaustive and that other operations can be performed as well before, after, or between any of the illustrated operations. Further, some of the operations may be performed simultaneously, or in a different order than that shown in FIG. 6.

Referring to FIG. 6, method 600 starts at operation 602, in which a first set of erase pulses may be applied to erase the block of memory cells in a first set of erase cycles, respectively. The first set of erase pulses may include a first set of erase voltages (including one or more first erase voltages) applied in the first set of erase cycles, respectively. The one or more first erase voltages may have varied voltage values.

Specifically, in each of the first set of erase cycles, responsive to an erase cycle count being smaller than a cycle threshold, peripheral circuits 402 may apply a corresponding first erase voltage to erase the block of memory cells and a corresponding verify voltage to verify the erasing of the block of memory cells. Peripheral circuits 402 may record the erase cycle count indicative of the number of erase cycles already applied to erase the block of memory cells.

For example, peripheral circuits 402 may apply a first one of the first erase voltages to erase the block and subsequently apply a verify voltage to verify the erasing of the block (e.g., to verify whether the erasing of the block is successful). Peripheral circuits 402 may record the erase cycle count to be 1. If the erasing of the block by the first one of the first erase voltages is successful, then method 600 may be terminated. If (a) the erasing of the block by the first one of the first erase voltages fails and (b) the erase cycle count is smaller than the cycle threshold, peripheral circuits 402 may continue to apply a second one of the first erase voltages to erase the block and a verify voltage to verify the erasing of the block. Peripheral circuits 402 may update the erase cycle count to 2. If the erasing of the block by the second one of the first erase voltages is successful, then method 600 may be terminated. If (a) the erasing of the block by the second one of the first erase voltages also fails and (b) the erase cycle count is smaller than the cycle threshold, peripheral circuits 402 may continue to apply a third one of the first erase voltages to erase the block and a verify voltage to verify the erasing of the block. By performing similar operations, peripheral circuits 402 may continue to apply a next one of the first erase voltages to erase the block and a verify voltage to verify the erasing of the block, if the erase cycle count is smaller than the cycle threshold and the erasing of the block is not successful yet. When the erase cycle count reaches the cycle threshold, method 600 may proceed to operation 604.

In some implementations, the cycle threshold can be any suitable value configured according to actual needs, which is not limited here. For example, the cycle threshold can be any integer in a range between 3 and 6 (3≤the cycle threshold≤6). In another example, the cycle threshold can be smaller than 3 or greater than 6, which is not limited herein. The cycle threshold may be smaller than the maximum cycle count configured for the erase operation.

At operation 604, as illustrated in FIG. 6, in which a second set of erase pulses can be applied to erase the block of memory cells in a second set of erase cycles, respectively, responsive to the erase cycle count reaching the cycle threshold. The second set of erase pulses may include a second set of erase voltages (including one or more second erase voltages) applied in the second set of erase cycles, respectively. Each of the one or more second erase voltages may have a respective voltage value smaller than one of the one or more first erase voltages. In some implementations, the one or more second erase voltages may have an identical voltage value.

Specifically, in each of the second set of erase cycles, responsive to the erase cycle count being equal to or greater than the cycle threshold and smaller than the maximum cycle count, peripheral circuits 402 may apply a corresponding second erase voltage to erase the block and a corresponding verify voltage to verify the erasing of the block. Peripheral circuits 402 may also update the erase cycle count thereof. If the erase cycle count reaches the maximum cycle count and the erasing of the block is not successful yet, peripheral circuits 402 may terminate the erasing of the block. The erase operation on the block fails. In some implementations, the block may be marked as a malfunctioning block that cannot be reused.

For example, when the erase cycle count reaches the cycle threshold and the erasing of the block is not successful yet, peripheral circuits 402 may start applying a first one of the second erase voltages to erase the block and subsequently apply a verify voltage to verify the erasing of the block. Peripheral circuits 402 may update the erase cycle accordingly. If the erasing of the block by the first one of the second erase voltages is successful, then method 600 may be terminated. If (1) the erasing of the block by the first one of the second erase voltages fails and (2) the erase cycle count is equal to or greater than the cycle threshold and smaller than the maximum cycle count, peripheral circuits 402 may continue to apply a second one of the second erase voltages to erase the block and a verify voltage to verify the erasing of the block. Peripheral circuits 402 may then update the erase cycle count accordingly. If the erasing of the block by the second one of the second erase voltages is successful, then method 600 may be terminated. If (1) the erasing of the block by the second one of the second erase voltages also fails and (2) the erase cycle count is equal to or greater than the cycle threshold and smaller than the maximum cycle count, peripheral circuits 402 may continue to apply a third one of the second erase voltages to erase the block and a verify voltage to verify the erasing of the block. By performing similar operations, peripheral circuits 402 may continue to apply a next one of the second erase voltages to erase the block and a verify voltage to verify the erasing of the block, if (1) the erase cycle count is equal to or greater than the cycle threshold and smaller than the maxim cycle count and (2) the erasing of the block is not successful yet. When the erase cycle count reaches the maximum cycle count and the erasing of the block is not successful yet, method 600 may terminate, and the erase operation on the block fails.

In some implementations, the identical voltage value of the second erase voltages can be smaller than a voltage value of one of the first erase voltages. For example, the identical voltage value of the second erase voltages can be smaller than a voltage value of the last one of the first erase voltages. In some other implementations, the identical voltage value of the second erase voltages can be equal to or greater than a voltage value of one of the first erase voltages. For example, the identical voltage value of the second erase voltages can be equal to or greater than a voltage value of the last one of the first erase voltages.

In some implementations, an ISPE scheme can be applied to erase the block of memory cells. For example, the first erase voltages in the first set of erase voltages can be increment step pulses. The second erase voltages in the second set of erase cycles can be pulses having the identical voltage value. In some implementations, the identical voltage value of the second erase voltages can be smaller than the largest voltage value of the increment step pulses.

FIG. 7 illustrates a flowchart of another method 700 for operating a memory device, according to some aspects of the present disclosure. The memory device may be any suitable memory device disclosed herein, such as memory device 104, 302, or 400. The memory device may include at least a block of memory cells. Method 700 may be performed for an erase operation on the block of memory cells. Method 700 may be implemented by peripheral circuits 402, such as control logic 512, row decoder/word line driver 508, and page buffer/sense amplifier 504. It is understood that the operations shown in method 700 may not be exhaustive and that other operations can be performed as well before, after, or between any of the illustrated operations. Further, some of the operations may be performed simultaneously, or in a different order than that shown in FIG. 7.

Referring to FIG. 7, method 700 starts at operation 702, in which the block of memory cells can be pre-programmed. For example, peripheral circuits 402 may pre-program the block of memory cells before performing the erase operation on the block. An erase cycle count can be initialized to be 0.

Method 700 may proceed to operation 704, as illustrated in FIG. 7, in which a first erase voltage can be applied to erase the block of memory cells.

Method 700 may proceed to operation 706, as illustrated in FIG. 7, in which a verify voltage can be applied to verify the erasing of the block of memory cells by the first erase voltage. The erase cycle count can be increased by 1.

Method 700 may proceed to operation 708, as illustrated in FIG. 7, in which it is determined whether the erasing of the block of memory cells is successful. Responsive to the erasing of the block of memory cells is successful, method 700 may end. The erase operation on the block of memory cells succeeds. Otherwise, method 700 may proceed to operation 710.

At operation 710, as illustrated in FIG. 7, it is determined whether the erase cycle count reaches a maximum cycle count. Responsive to the erase cycle count being smaller than the maximum cycle count, method 700 may proceed to operation 712. Otherwise, method 700 may end.

At operation 712, as illustrated in FIG. 7, it is determined whether the erase cycle count is smaller than a cycle threshold. Responsive to the erase cycle count being smaller than the cycle threshold, method 700 may proceed to operation 714. Otherwise, method 700 may proceed to operation 716.

At operation 714, as illustrated in FIG. 7, a next first erase voltage can be applied to erase the block of memory cells. Then, method 700 may return to operation 706 to verify the erasing of the block. In some implementations, the first erase voltages applied in method 700 can be increment step pulses.

At operation 716, as illustrated in FIG. 7, a second erase voltage can be applied to erase the block of memory cells. Then, method 700 may also return to operation 706 to verify the erasing of the block. In some implementations, all the second erase voltages applied in method 700 can be pulses having the same voltage value. In some implementations, each second erase voltage applied in method 700 may have a voltage value smaller than that of at least one of the first erase voltages applied in method 700.

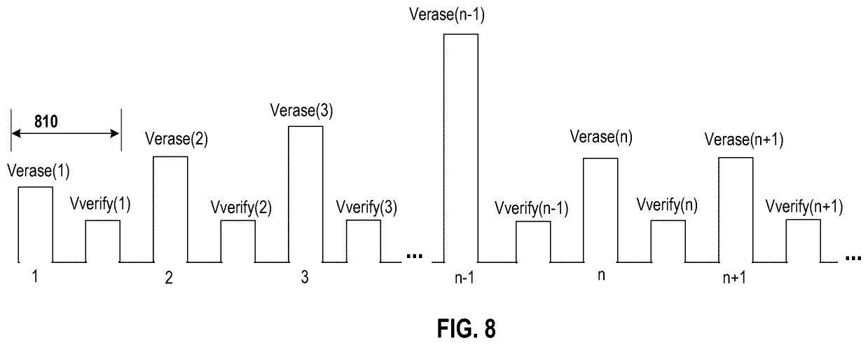

FIG. 8 illustrates a waveform of erase voltages and verify voltages applied in a plurality of erase cycles, according to some aspects of the present disclosure. A cycle threshold can be denoted as n. During an erase operation, initially, a first set of erase cycles (e.g., n−1 erase cycles) can be performed to erase a block of memory cell, as described above with reference to FIG. 6. A first set of erase voltages including Verase(1), Verase(2), Verase(3), . . . , and Verase(n−1), as well as a first set of verify voltages Vverify(1), Vverify(2), Vverify(3), . . . , and Vverify(n−1), can be respectively applied in the first set of erase cycles to erase the block. For example, a first erase cycle 810 is illustrated in FIG. 8, which includes the erase voltage Verase(1) and the verify voltage Vverify(1). The first set of erase voltages Verase(1), Verase(2), Verase(3), . . . , and Verase(n−1) can be increment step pulses. The first set of verify voltages Vverify(1), Vverify(2), Vverify(3), . . . , and Vverify(n−1) can be verify voltages having the same voltage value or different voltage values, which is not limited herein.

When an erase cycle count reaches the cycle threshold (e.g., the number of erase cycles applied to erase the block reaches n), a second set of erase cycles can be performed to erase the block of memory cell, as described above with reference to FIG. 6. A second set of erase voltages including Verase(n), Verase(n+1), . . . and a second set of verify voltages Vverify(n), Vverify(n+1), . . . can be respectively applied in the second set of erase cycles to erase the block of memory cells. The second set of erase voltages Verase(n), Verase(n+1), . . . can include pulses having the same voltage value. The second set of verify voltages Vverify(n), Vverify(n+1) . . . can be verify voltages having the same voltage value or different voltage values, which is not limited herein. When the erase cycle count reaches a maximum cycle count, and the erasing of the block is not successful yet, the erase operation on the block fails.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described example implementations, but should be defined only in accordance with the following claims and their equivalents.

What is claimed is:

1. A method of operating a memory device comprising at least a block of memory cells, the method comprising:
applying a first set of erase pulses to erase the block of memory cells in a first set of erase cycles, respectively, wherein the first set of erase pulses comprises one or more first erase voltages having varied voltage values; and
responsive to an erase cycle count reaching a cycle threshold, applying a second set of erase pulses to erase the block of memory cells in a second set of erase cycles, respectively, wherein the second set of erase pulses comprises one or more second erase voltages each of which has a respective voltage value smaller than a voltage value of one of the one or more first erase voltages.

2. The method of claim 1, wherein the cycle threshold is in a range between 3 and 6.

3. The method of claim 1, wherein the respective voltage value of each of the one or more second erase voltages is identical.

4. The method of claim 1, wherein applying the first set of erase pulses to erase the block of memory cells in the first set of erase cycles, respectively, comprises:
in each of the first set of erase cycles,
responsive to the erase cycle count being smaller than the cycle threshold, applying a corresponding first erase voltage to erase the block of memory cells; and
applying a verify voltage to verify the erasing of the block of memory cells.

5. The method of claim 1, wherein applying the second set of erase pulses to erase the block of memory cells in the second set of erase cycles, respectively, further comprises:
in each of the second set of erase cycles,
responsive to the erase cycle count being equal to or greater than the cycle threshold and smaller than a maximum cycle count, applying a corresponding second erase voltage to erase the block of memory cells; and
applying a verify voltage to verify the erasing of the block of memory cells.

6. The method of claim 4, further comprising:
updating the erase cycle count that indicates a total number of erase cycles already performed to erase the block of memory cells.

7. The method of claim 5, further comprising:
responsive to the erase cycle count reaching the maximum cycle count, terminating the erasing of the block of memory cells.

8. The method of claim 1, wherein:
an increment step pulse erase (ISPE) scheme is applied to erase the block of memory cells;
the one or more first erase voltages comprise one or more increment step pulses; and
the one or more second erase voltages comprise one or more pulses having an identical voltage value.

9. A memory device, comprising:
at least a block of memory cells; and
a peripheral circuit coupled to the block of memory cells and configured to:
apply a first set of erase pulses to erase the block of memory cells in a first set of erase cycles, respectively, wherein the first set of erase pulses comprises one or more first erase voltages having varied voltage values; and
responsive to an erase cycle count reaching a cycle threshold, apply a second set of erase pulses to erase the block of memory cells in a second set of erase cycles, respectively, wherein the second set of erase pulses comprises one or more second erase voltages each of which has a respective voltage value smaller than a voltage value of one of the one or more first erase voltages.

10. The memory device of claim 9, wherein the cycle threshold is in a range between 3 and 6.

11. The memory device of claim 9, wherein the respective voltage value of each of the one or more second erase voltages is identical.

12. The memory device of claim 9, wherein to apply the first set of erase pulses to erase the block of memory cells in the first set of erase cycles, respectively, the peripheral circuit is further configured to:
in each of the first set of erase cycles,
responsive to the erase cycle count being smaller than the cycle threshold, apply a corresponding first erase voltage to erase the block of memory cells; and
apply a verify voltage to verify the erasing of the block of memory cells.

13. The memory device of claim 9, wherein to apply the second set of erase pulses to erase the block of memory cells in the second set of erase cycles, respectively, the peripheral circuit is further configured to:
in each of the second set of erase cycles,
responsive to the erase cycle count being equal to or greater than the cycle threshold and smaller than a maximum cycle count, apply a corresponding second erase voltage to erase the block of memory cells; and
apply a verify voltage to verify the erasing of the block of memory cells.

14. The memory device of claim 12, wherein the peripheral circuit is further configured to:
update the erase cycle count that indicates a total number of erase cycles already performed to erase the block of memory cells.

15. The memory device of claim 13, wherein the peripheral circuit is further configured to:
responsive to the erase cycle count reaching the maximum cycle count, terminate the erasing of the block of memory cells.

16. The memory device of claim 9, wherein:
an increment step pulse erase (ISPE) scheme is applied to erase the block of memory cells;
the one or more first erase voltages comprise one or more increment step pulses; and
the one or more second erase voltages comprise one or more pulses having an identical voltage value.

17. A system, comprising:
a memory device configured to store data and comprising:
at least a block of memory cells; and
a peripheral circuit coupled to the block of memory cells and configured to perform operations comprising:
applying a first set of erase pulses to erase the block of memory cells in a first set of erase cycles, respectively, wherein the first set of erase pulses comprises one or more first erase voltages having varied voltage values; and
responsive to an erase cycle count reaching a cycle threshold, applying a second set of erase pulses to erase the block of memory cells in a second set of erase cycles, respectively, wherein the second set of erase pulses comprises one or more second erase voltages each of which has a respective voltage value smaller than a voltage value of one of the one or more first erase voltages; and
a memory controller coupled to the memory device and configured to control the memory device to perform the operations.

18. The system of claim 17, wherein:
the peripheral circuit comprises at least one processor, a read-only memory (ROM) storing first instructions, and a random-access memory (RAM) storing second instructions;
the first instructions comprise a first instruction segment, a second instruction segment, and a third instruction segment, wherein the second instructions stored in the RAM are configured to replace the second instruction segment stored in the ROM; and
the at least one processor is configured to perform the operations by executing the first instruction segment stored in the ROM, the second instructions stored in the RAM, and the third instruction segment stored in the ROM.

19. The system of claim 17, wherein the respective voltage value of each of the one or more second erase voltages is identical.

20. The system of claim 17, wherein to apply the first set of erase pluses to erase the block of memory cells in the first set of erase cycles, respectively, the peripheral circuit is further configured to:
in each of the first set of erase cycles,
responsive to the erase cycle count being smaller than the cycle threshold, apply a corresponding first erase voltage to erase the block of memory cells; and
apply a verify voltage to verify the erasing of the block of memory cells.
